(19) United States
(12) Patent Application Publication
(10) Pub. No.: US 2004/0051452 A1
(43) Pub. Date: Mar. 18, 2004

(54) Display apparatus and method of manufacturing the same

(76) Inventors: Hitoshi Tamashiro, Kanagawa (JP); Yuichi Iwase, Kanagawa (JP)

Correspondence Address: ROBERT J. DEPKE LEWIS T. STEADMAN, HOLLAND & KNIGHT LLC, 131 SOUTH DEARBORN, 30TH FLOOR, CHICAGO, IL, 60603, US

(21) Appl. No.: 10/658,571

(22) Filed: Sep. 9, 2003

(30) Foreign Application Priority Data
Sep. 17, 2002 (JP) JP2002-269406

(51) Int. Cl. H01J 1/62

(52) U.S. Cl. 313/512

(57) ABSTRACT

An organic EL display apparatus comprises a panel substrate provided with light emitting devices and driving electrodes for driving the light emitting devices, the light emitting devices and the driving electrodes forming a light emission region and an electrode region, and a sealing substrate adhered to the panel substrate through a sealing resin. The sealing substrate is provided with a relief portion for the sealing resin at its portion opposed to the outside of the light emission region L in the condition of being adhered to the panel substrate. The relief portion prevents the diffusion of the uncured sealing resin toward external electrodes beyond it, thereby securing conduction between the external electrodes and external terminals and promising a higher reliability and a higher yield of the display apparatus.

### BACKGROUND OF THE INVENTION

The present invention relates to a display apparatus and a method of manufacturing the same, particularly to an organic electroluminescence display apparatus and a method of manufacturing the same.

As one of the flat type display apparatuses called flat panel displays, there is an organic electroluminescence (hereinafter referred to as organic EL) display apparatus using organic EL devices as light emitting devices. The organic EL display apparatus is of a self-emission type and, therefore, has the feature of a wide angle of visibility. In addition, the organic EL display apparatus has a design in which only the desired pixels are brought into light emission, so that it has the merit of less power consumption as compared with a liquid crystal display apparatus, which is the backlight type display apparatus.

In a general structure of the organic EL device, an organic material is sandwiched between an anode and a cathode. The light emission mechanism of the organic EL device resides in that positive holes are injected from the anode into an organic layer formed of the organic material, whereas electrons are injected from the cathode, and the positive holes and electrons thus injected are re-coupled with each other, thereby emitting light. At present, the organic EL device can provide a luminance of several hundreds to several tens of thousands of candela per square meters at a driving voltage of not more than 10 V. Besides, by appropriately selecting the organic material, it is possible to construct a multicolor display or full-color display apparatus.

The organic EL device has some problems. When moisture or oxygen penetrates into the organic layer, the organic layer is crystallized, resulting in the generation of a non-luminous point called dark spot. The dark spot grows with the lapse of time, causing a shortening of the life of the organic EL device. As a configuration for solving this problem, an organic EL display apparatus constituted as shown in FIG. 5 has been disclosed. As shown in FIG. 5, a panel substrate 1 is provided with organic EL devices, and a sealing substrate 3 is adhered onto the display region of the panel substrate 1 through a sealing resin 2. A UV-curable resin or a thermosetting resin is used as the sealing region 2, which is generally cured after the sealing substrate 3 is adhered. The sealing resin 2 is formed on the light emission region (also called display region), and external electrodes 4 and external terminals 5 are arranged in the periphery of the light emission region. The organic EL devices are driven by applying a driving voltage to the external electrodes 4 and the external terminals 5.

However, in the conventional organic EL display apparatus described above referring to FIG. 5, the sealing resin for sealing the organic EL devices may, before curing, flow out to the side of the external electrodes, thereby contaminating the external electrodes. Upon such a contamination, the contact between the external electrodes and the external terminals becomes imperfect, and it is difficult to secure conduction between the external electrodes and the external terminals, with the result that the organic EL devices cannot be driven.

In addition, in the manufacturing process of the organic EL display apparatus, in order to enhance productivity a multiple-product production mode is often adopted in which a plurality of organic EL display apparatuses 6 are produced from a single sheet of panel substrate 1, as shown in FIG. 6A. In this case, as shown in FIG. 6B, the sealing substrate 3 also is of a large size, in the same manner as the panel substrate 1. For example, the sealing resin 2 is applied in correspondence with each of a plurality of light emission regions (also called display regions) formed on the panel substrate 1, then a single sheet of sealing substrate 3 is adhered onto the sealing resin 2 on each of the light emission regions, and the sealing resin 2 is cured. Thereafter, the unrequired portions of the sealing substrate 3 located between the light emission regions are removed. In such a so-called multiple-product production mode, the panel substrate 1 and the sealing substrate 3 are adhered to each other through the sealing resin 2, so that capillarity is generated in the sealing resin 2 between the panel substrate 1 and the sealing substrate 3. Therefore, as for example shown in FIG. 6C, there arises with high possibility the problem that the uncured sealing resin 2 would flow out to the side of the external electrodes 4, to cover the external electrodes 4. This leads to a serious defect that the connection between the external electrodes 4 and the external terminals 5 (see FIG. 5) fails.

The present invention has been made in consideration of the above problems. Accordingly, it is an object of the present invention to provide a display apparatus and a method of manufacturing the same such that the diffusion of a sealing resin to the external electrode side is prevented at the time of sealing organic EL devices with the sealing resin and that the display apparatus can be stably manufactured in a high yield.

### SUMMARY OF THE INVENTION

The present invention resides in a display apparatus and a method of manufacturing the same, provided for attaining the above object.

In accordance with one aspect of the present invention, there is provided a display apparatus including a panel substrate provided with light emitting devices and driving electrodes for driving the light emitting devices, the light emitting devices and the driving electrodes forming a light emission region and an electrode region and a sealing substrate adhered to the panel substrate through a sealing resin. The sealing substrate is provided with a relief portion for the sealing resin at its portion opposed to the outside of the light emission region in the condition where the sealing substrate is adhered to the panel substrate.

In the above display apparatus, the sealing substrate is provided with the relief portion for the sealing resin at its portion opposed to the outside of the light emission region in the condition where the sealing substrate is adhered to the panel substrate, and, therefore, even if the uncured sealing resin flows out between the panel substrate and the sealing substrate toward the electrode region on the outside of the light emission region due to the capillarity at the time of adhering the panel substrate and the sealing substrate to each other through the sealing resin, the sealing resin thus flowing out is made to flow into the relief portion. Therefore, the sealing resin cannot flow out to the electrode region side beyond the relief portion, and the sealing resin is cured in the position of the relief portion.

Thus, the diffusion of the uncured sealing resin toward the electrode region side can be prevented, and the conduction between the external electrodes in the electrode region and the external terminals can be secured. Therefore, a display apparatus with high reliability, excellent yield and high quality can be provided.

In accordance with another aspect of the present invention, there is provided a method of manufacturing a display apparatus including a panel substrate provided with light emitting devices and driving electrodes for driving the light emitting devices, the light emitting devices and the driving electrodes forming a light emission region and an electrode region, and a sealing substrate adhered to the panel substrate through a sealing resin. The method includes the step of providing the sealing substrate with a relief portion for the sealing resin at a portion of the sealing substrate which portion is opposed to the outside of the light emission region in the condition where the sealing substrate is adhered to the panel substrate.

In the above method of manufacturing a display apparatus, there is the step of providing the sealing substrate with the relief portion for the sealing resin at a portion of the sealing substrate which portion is opposed to the outside of the light emission region in the condition where the sealing substrate is adhered to the panel substrate, and, therefore, even if the uncured sealing resin flows out between the panel substrate and the sealing substrate toward the electrode region on the outside of the light emission region due to the capillarity at the time of adhering the panel substrate and the sealing substrate to each other through the sealing resin, the sealing resin thus flowing out is made to flow into the relief portion. Therefore, the sealing resin cannot flow out to the electrode region side beyond the relief portion, and the sealing resin can be cured in the position of the relief portion for the sealing resin.

Thus, the diffusion of the uncured sealing resin toward the electrode region can be prevented by the relief portion, and the conduction between the external electrodes in the electrode region and the external terminals can be secured. Therefore, a display apparatus with high reliability and high quality can be manufactured in a high yield. In addition, in the case of a multiple-product production mode, the manufacturing method according to the present invention is very effective because it can securely prevent the uncured sealing resin from diffusing toward the electrode region.

The above and other objects, features and advantages of the present invention will become apparent from the following description and appended claims, taken in conjunction with the accompanying drawings which show by way of example some preferred embodiments of the invention.

### BRIEF DESCRIPTION OF THE DRAWINGS

FIGS. 1A to 1C illustrate an embodiment of a display apparatus according to the present invention, in which FIG. 1A shows a plan view and a sectional view of a sealing substrate, FIG. 1B shows the condition where a panel substrate and the sealing substrate are adhered to each other, and FIG. 1C shows a layout of an organic EL display apparatus in which the sealing substrate is adhered to the panel substrate through a sealing resin.

FIGS. 2A and 2B are perspective views showing a first embodiment of a relief portion.

FIG. 3 is a perspective view showing a second embodiment of the relief portion.

FIG. 4 is a perspective view showing a third embodiment of the relief portion.

FIGS. 5A and 5B illustrate an exemplary constitution of a conventional organic EL display apparatus, in which FIG. 5A is a plan layout view, and FIG. 5B is a side view.

FIGS. 6A to 6C illustrate generally an organic EL display apparatus and a method of manufacturing the same in the case of the multiple-product production mode according to the related art, in which FIG. 6A is a plan layout view showing the arrangement onto a panel substrate, FIG. 6B is a sectional view for illustrating a sealing step for adhering a sealing substrate to the panel substrate through a sealing resin, and FIG. 6C is a plan layout view for illustrating the condition of the sealing resin.

### DESCRIPTION OF THE PREFERRED EMBODIMENTS

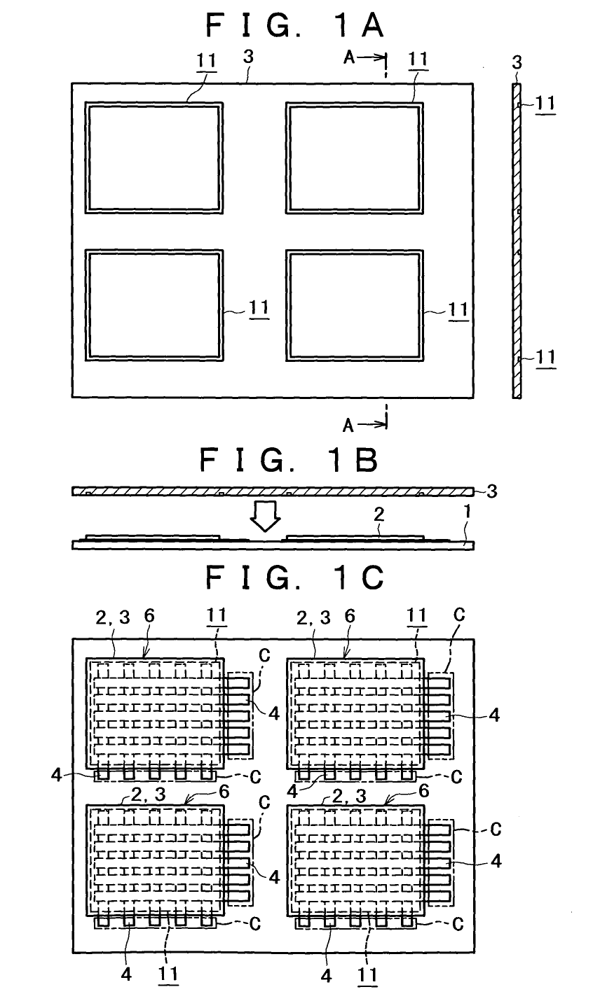

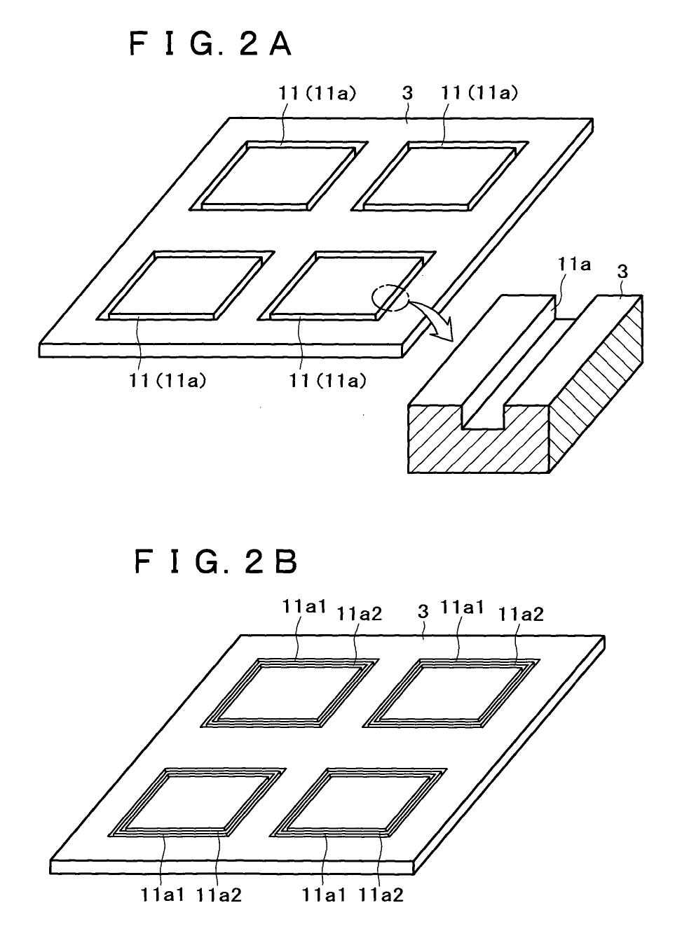

One embodiment of the display apparatus according to the present invention will be described referring to FIGS. 1 to 4. FIGS. 1A to 1C show an organic EL display apparatus as an example, in which FIG. 1A shows a plan view and a sectional view of a sealing substrate, FIG. 1B illustrates the adhered condition of a panel substrate and the sealing substrate, and FIG. 1C is a layout view of the organic EL display apparatus in which the sealing substrate is adhered to the panel substrate through a sealing resin. In reading the following description made referring to FIGS. 2 to 4, see also FIGS. 1A to 1C.

As shown in FIGS. 1A to 1C, an organic EL display apparatus 6 comprises a panel substrate 1 provided with light emitting devices and driving electrodes for driving the light emitting devices, the light emitting devices and the driving electrodes forming a light emission region L (intersection regions of the electrodes), with an electrode region being formed on the outside of the light emission region L, and a sealing substrate 3 adhered onto the panel substrate 1 through a sealing resin 2. The sealing resin 2 is applied onto the light emission region L, and is composed, for example, of a UV-curable resin or a thermosetting resin. The sealing substrate 3 is provided with a relief portion 11 at its portion opposed to the region on the outside of the light emission region L, namely, opposed to the electrode region formed on the outside of the light emission region L in the condition where the sealing substrate 3 is adhered to the panel substrate 1.

The amount of the sealing region 2 diffused due to the capillarity at the time of adhering the sealing substrate 3 onto the panel substrate 1 through the sealing resin 2 is determined by the material of the sealing resin 2, the spacing between the panel substrate 1 and the sealing substrate 3, and the like; therefore, the shape of the relief portion 11 may be any shape insofar as it includes a recessed portion for inhibiting the diffusion of the sealing resin 2.

As shown in FIG. 2A, a first embodiment of the relief portion 11 is composed of a groove 11a. The sectional shape of the groove 11a may be any shape, but, in view of easy processability, a rectangular section or a U-shaped section is preferably selected. In addition, as shown in FIG. 2B, the groove 11a may, for example, be composed of a multiplicity of grooves 11a1 and 11a2 (a double-groove mode is shown as an example) formed at a portion of the sealing substrate 3 which portion is opposed to the electrode region formed on the outside of the light emission region L.

The shape of the groove 11a is merely an example, and the shape is appropriately selected according to the material of the sealing resin 2, the amount of the sealing resin 2, the spacing between the panel substrate 1 and the sealing substrate 3, the area of the light emission region L, etc.; however, the groove 11a must at least have such a volume as follows. Namely, in order that the sealing resin 2 for adhering the panel substrate 1 and the sealing substrate 3 will not cover those portions C of the external electrodes 4 in the electrode region which are connected to external terminals (not shown), the groove 11a must have such a volume that the sealing resin 2 tending to diffuse toward end portions of the external electrodes 4 is led into the groove 11a and is thereby prevented from flowing out toward the end portions of the external electrodes 4 beyond the groove 11a. For example, the volume of the groove 11a is so determined that an amount of the sealing resin 2 for sufficiently covering the light emission region L is secured and the amount is smaller than the volume of the space formed between the panel substrate 1 and the sealing substrate 3 in the areas of the light emission region L and the groove 11a.

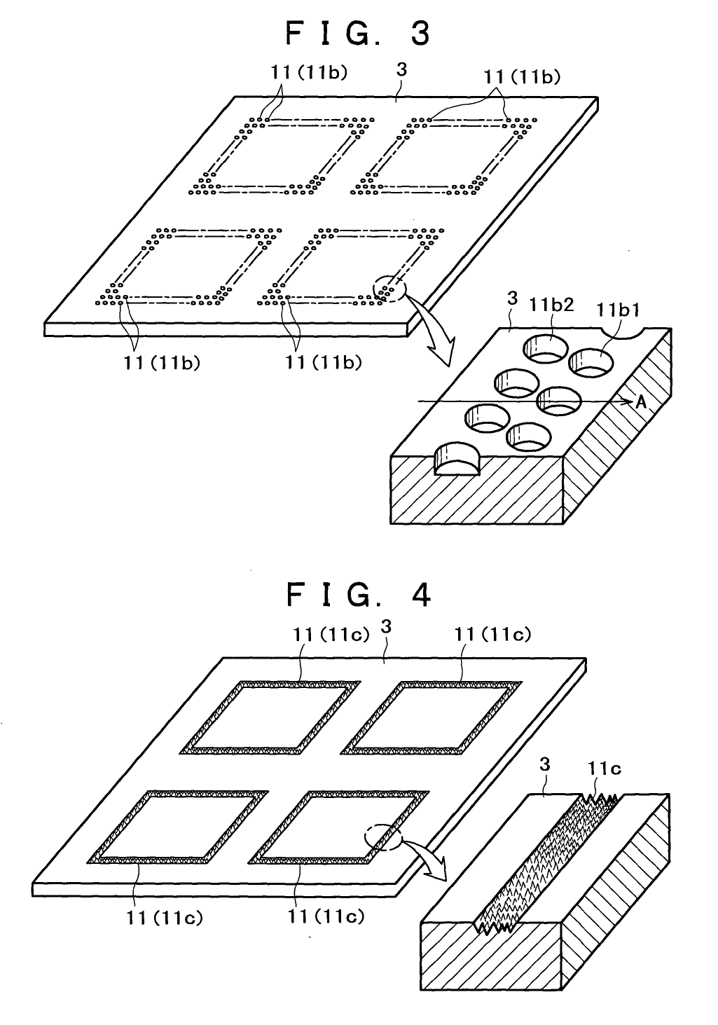

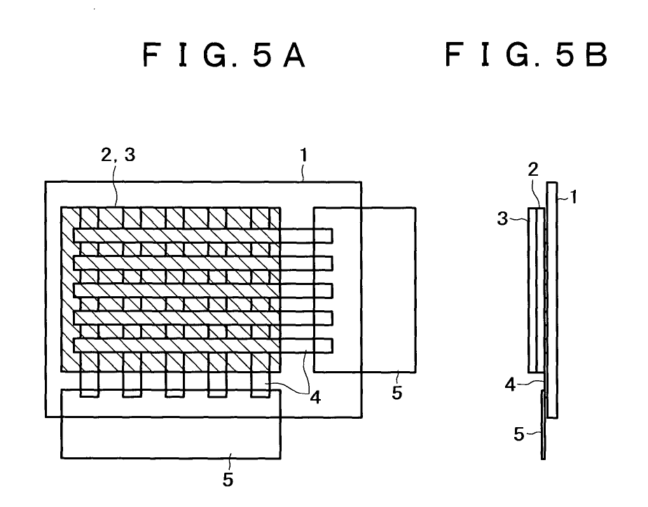

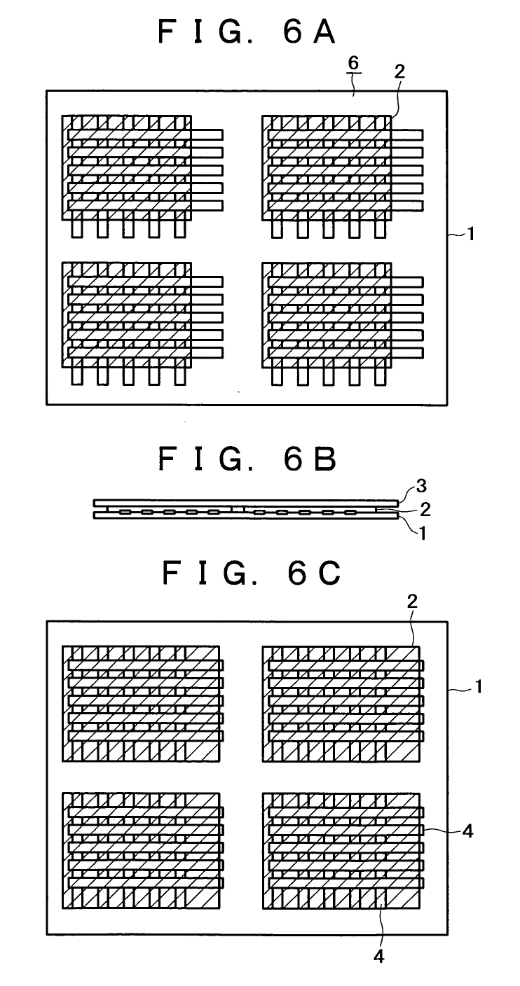

As shown in FIG. 3, a second embodiment of the relief portion 11 is composed of a multiplicity (in the figure, double) of hole rows consisting of a plurality of holes 11b. The sectional shape of the holes 11b as viewed from the principal surface side of the sealing substrate 3 may be any shape, but, in view of easy processability, a circular section or a rectangular section is preferably selected. Of the holes 11b, the holes 11b1 in the first row and the holes 11b2 in the second row are so laid out that the sealing resin 2 flowing in the flow direction A at any location will encounter the hole 11b1 in the first row or the hole 11b2 in the second row without fail. For example, the holes 11b1 in the first row and the holes 11b2 in the second row are laid out alternately, with respect to the arrangement direction of the holes 11b. This ensures that the sealing resin 2 tending to diffuse is securely led into the holes 11b.

Besides, in order that the sealing resin 2 will not cover those portions C of the external electrodes 4 in the electrode region which are connected to the external terminals (not shown) at the time of adhering the panel substrate 1 and the sealing substrate 3 to each other through the sealing resin 2, the volume of the holes 11b must be such a volume that the sealing resin 2 tending to flow out toward the end portions of the external electrodes 4 is led into the holes 11b and is thereby prevented from diffusing toward the end portions of the external electrodes 4 beyond the row of the holes 11b. The volume of the holes 11b is appropriately selected according to the amount of the sealing resin used for adhesion, the spacing between the panel substrate 1 and the sealing substrate 3, the area of the light emission region L, etc. For example, the volume of the holes 11b is so determined that an amount of the sealing resin 2 for sufficiently covering the light emission region L is secured and the amount is smaller than the volume of the space formed between the panel substrate 1 and the sealing substrate 3 in the areas of the light emission region L and the rows of the holes 11b.

As shown in FIG. 4, a third embodiment of the relief portion 3 is composed of a rough surface 11c formed by roughening a surface of the sealing substrate 3. The rough surface 11c is formed, for example, by roughening a surface of the sealing substrate 3 by sandblasting, etching or the like to form a surface having a surface roughness.

In order to ensure that the sealing resin 2 will not cover those portions of the external electrodes in the electrode region which are connected to the external terminals (not shown) at the time of adhering the panel substrate 1 and the sealing substrate 3 to each other through the sealing resin 2, the relief portion in the rough surface 11c must have such a volume that the sealing resin 2 tending to diffuse toward the end portions of the external electrodes 4 is led into the recessed portions of the rough surface 11c and is thereby prevented from flowing out toward the end portions of the external electrodes 4 beyond the rough surface 11c. The volume of the recessed portions in the rough surface 11c is appropriately selected according to the amount of the sealing resin 2 used for adhesion, the spacing between the panel substrate 1 and the sealing substrate 3, the area of the light emission region L, etc. For example, the volume of the recessed portions in the rough surface 11c is so determined that an amount of the sealing resin 2 for sufficiently covering the light emission region L is secured and the amount is smaller than the volume of the space formed between the panel substrate 1 and the sealing substrate 3 in the areas of the light emission region L and the rough surface 11c.

Thus, in order that the sealing resin 2 will not reach the contact region C of the external electrodes 4 with the external terminals (not shown) at the time of adhering the panel substrate 1 and the sealing substrate 3 to each other through the sealing resin 2, the relief portion 11 and the space formed between the relief portion 11 and the panel substrate 1 altogether secure such a volume that the diffusion of the sealing resin 2 can be inhibited.

In the display apparatus as above-described, the sealing substrate 3 is provided with the relief portion 11 at its portion opposed to the outside of the light emission region L in the condition where the sealing substrate 3 is adhered to the panel substrate 1, and, therefore, even if the uncured sealing resin 2 flows out between the panel substrate 1 and the sealing substrate 3 toward the electrode region on the outside of the light emission region L due to the capillarity at the time of adhesion of the panel substrate 1 and the sealing substrate 3 through the sealing resin 2, the sealing resin 2 thus flowing out is made to flow into the relief portion 11. Therefore, the sealing resin 2 will not diffuse to the side of the electrode region E beyond the relief portion 11 but will be cured in the position of the relief portion 11.

Therefore, the contamination of the external electrodes 4 in the electrode region with the sealing resin 2 is prevented, and there is no possibility of the serious defect that the electrical conduction between the external electrodes 4 and the external terminals (not shown) cannot be secured and, hence, the organic EL display apparatus cannot be driven. In other words, it is possible to provide an organic EL display apparatus in which the electrical conduction between the external electrodes and the external terminals is secured and which has high reliability.

Next, one embodiment of a method of manufacturing a display apparatus according to the present invention will be described referring to FIGS. 1 to 4.

As shown in FIG. 1, a sealing substrate 3 to be adhered to a panel substrate 1 through a sealing resin 2 is provided on its adhering surface side with rectangular frame shaped relief portions 11 surrounding individual light emission regions L, in respective correspondence with the light emission regions L formed on the panel substrate 1. Therefore, for example, in a configuration where four light emission regions L are formed on the panel substrate 1, the sealing substrate 3 is provided with the rectangular frame shaped relief portions 11 (for example, grooves 11a) at its portions on the outside of its regions opposed respectively to the light emission regions L.

The amount of the sealing resin 2 diffused due to the capillarity at the time of adhesion of the sealing substrate 3 onto the panel substrate 1 through the sealing resin 2 is determined by the material of the sealing resin 2, the spacing between the panel substrate 1 and the sealing substrate 3, etc., and, therefore, the shape of the relief portions 11 may be any shape insofar as it includes a recessed portion for inhibiting the diffusion of the sealing resin 2.

The relief portion 11 may be composed, for example, of the groove 11a, as has been described above referring to FIG. 2A. The sectional shape of the groove 11a may be any shape, but, in view of easy processability, a rectangular section or a U-shaped section is preferably selected. In addition, as shown in FIG. 2B, the groove 11a may be formed in a rectangular frame shape and in a plurality of rows (in the figure, two rows, as an example) at that portion of the sealing substrate 3 which is opposed to the outside of the light emission region L.

As a method of forming the grooves 11a, for example, a method was used in which a mask (not shown) provided with openings at the regions where the grooves 11a are to be formed was used, and grooves 1 mm in width and 0.2 mm in depth were formed in the areas of the openings of the mask by sandblasting, for example. The grooves 11a may be formed also by etching while using a similar mask.

The shape of the groove 11a is merely an example, and is appropriately selected according to the material of the sealing resin 2, the amount of the sealing resin 2, the spacing between the panel substrate 1 and the sealing substrate 3, the area of the light emission region L, etc.; however, the groove 11a must at least have such a volume as follows. It is necessary that when the panel substrate 1 and the sealing substrate 3 are adhered to each other through the sealing resin 2, those portions C of the external electrodes 4 in the electrode region which are connected to the external terminals (not shown) should not be covered with the sealing resin 2. To meet this requirement, the groove 11a must have such a volume that the sealing resin 2 tending to diffuse toward end portions of the external electrodes 4 is made to flow into the groove 11a and is thereby prevented from flowing out toward the end portions of the external electrodes 4 beyond the groove 11a. For example, the volume of the groove 11a is so determined that an amount of the sealing resin 2 for sufficiently covering the light emission region L is secured and the amount is smaller than the volume of the space formed between the panel substrate 1 and the sealing substrate 3 in the areas of the light emission region L and the groove 11a.

The relief portion 11 may be composed, for example, of a multiplicity of rows of a plurality of holes 11b, as has been described referring to FIG. 3. The sectional shape of the holes 11b as viewed from the principal surface side of the sealing substrate 3 may be any shape, but, in view of easy processability, a circular section or a rectangular section is preferably selected. In addition, as shown in FIG. 2B, the groove 11a may be formed in a multiplicity of rows (in the figure, a double-row mode is shown as an example) at that portion of the sealing substrate 3 which is opposed to the electrode region formed on the outside of the light emission region L.

The shape of the holes 11b is merely an example, and the shape is appropriately selected according to the material of the sealing resin 2, the amount of the sealing resin 2, the spacing between the panel substrate 1 and the sealing substrate 3, the area of the light emission region L, etc.; however, the holes 11b must have such a volume as follows. It is necessary that when the panel substrate 1 and the sealing substrate 3 are adhered to each other through the sealing resin 2, those portions of the external electrodes 4 in the electrode region which are connected to the external terminals (not shown) should not be covered with the sealing resin 2. Therefore, the holes 11b must be formed to have such a volume that the sealing resin 2 tending to flow out toward end portions of the external electrodes 4 is led into the holes 11b and is thereby prevented from diffusing toward the end portions of the external electrodes 4 beyond the holes 11b. For example, the volume of the holes 11b is so determined that an amount of the sealing resin 2 for sufficiently covering the light emission region L is secured and the amount is smaller than the volume of the space formed between the panel substrate 1 and the sealing substrate 3 in the areas of the light emission region L and the rows of the holes 11b.

The relief portion 11 may be composed, for example, of a rough surface 11c, as has been described referring to FIG. 4. The rough surface 11c may be formed by roughening a surface of the sealing substrate 3, for example, by sandblasting, etching or the like to form a surface having a surface roughness.

The shape (for example, surface roughness) of the rough surface 11c is appropriately selected according to the material of the sealing resin 2, the amount of the sealing resin 2, the spacing between the panel substrate 1 and the sealing substrate 3, the area of the light emission region L, etc.; however, the rough surface 11c must at least be formed to have such a volume as follows. It is necessary that when the panel substrate 1 and the sealing substrate 3 are adhered to each other through the sealing resin 2, those portions C of the external electrodes 4 in the electrode region which are connected to the external terminals (not shown) should not be covered with the sealing resin 2. Therefore, recessed portions in the rough surface 11c must be formed to have such a volume that the sealing resin 2 tending to diffuse toward end portions of the external electrodes 4 is led into the recessed portions in the rough surface 11c and is thereby prevented from diffusing toward the end portions of the external electrodes 4 beyond the rough surface 11c. For example, the volume of the recessed portions in the rough surface 11c is so determined that an amount of the sealing resin 2 for sufficiently covering the light emission region L is secured and the amount is smaller than the volume of the space formed between the panel substrate 1 and the sealing substrate 3 in the areas of the light emission region L and the rough surface 11c.

Thus, in order that the sealing resin 2 will not reach the connection portion C of connection of the external electrodes 4 with the external terminals (not shown) by diffusion due to the capillarity at the time of adhesion of the panel substrate 1 and the sealing substrate 3 through the sealing resin 2, the relief portion 11 must be so formed that the relief portion 11 and the space region between the relief portion 11 and the panel substrate 1 altogether secure such a volume that the diffusion of the sealing resin 2 is inhibited.

After the sealing substrate 3 (see FIG. 1A) provided with the relief portions 11 as above-described is prepared, an appropriate amount of the sealing resin 2 for covering each light emission region L formed on the panel substrate 1 is applied in an uncured state to each light emission region L by use of a dispenser, for example, as shown in FIG. 1B. Next, the sealing substrate 3 is adhered to the panel substrate 1 through the sealing resin 2 thus applied. In this case, the sealing substrate 3 is adhered in such a manner that the projection images of the relief portions 11 formed in the sealing substrate 3 onto the panel substrate 1 surround the outside of the individual light emission regions L and that the sealing substrate 3 is located at a predetermined distance from the panel substrate 1.

In adhering the sealing substrate 3, the capillarity is generated between the panel substrate 1 and the sealing substrate 3, so that the uncured sealing resin 2 tends to diffuse toward the outside of the light emission regions L, namely, toward the electrode regions. The sealing resin 2 thus tending to diffuse flows into the relief portions 11 formed in the sealing substrate 3, and the diffusion is stopped by the relief portions 11. Therefore, the sealing resin 2 will not diffuse so as to cover those portions of the external electrodes 4 which are located on the outside of the relief portions 11. As a result, the light emission regions L can be sealed with the sealing resin 2, and the connection of the external electrodes 4 with the external terminals (not shown) can be secured. In addition, at the locations where the diffusion of the sealing resin 2 is stopped, pools of the sealing resin 2 are formed due to the sealing resin 2 having flowed into the relief portions 11. This promises an enhanced sealing effect.

Thereafter, the sealing resin 2 dwelling in the areas of the light emission regions L is cured; specifically, where the sealing resin 2 is a UV-curable resin, for example, it is cured by irradiation with UV rays, and where the sealing resin 2 is a thermosetting resin, for example, it is cured by heating. Furthermore, the unrequired sealing substrate 3 present between the light emission regions L is removed. In this manner, as shown in FIG. 1C, a plurality of organic EL display apparatuses 6 free of the unrequired diffusion of the sealing resin 2 between the panel substrate 1 and the sealing substrate 3 can be simultaneously produced from the single panel substrate 1.

In the above-described method of manufacturing the display apparatus, there is the step of providing the sealing substrate 3 with the relief portions 11 at its portions opposed to the outside of the light emission regions L in the condition of being adhered to the panel substrate 1, and, therefore, even if the uncured sealing resin 2 diffuses between the panel substrate 1 and the sealing substrate 3 toward the electrode regions on the outside of the light emission regions L due to the capillarity when the panel substrate 1 and the sealing substrate 3 are adhered to each other through the sealing resin 2, the sealing resin 2 thus flowing out is made to flow into the relief portions 11. Therefore, the sealing resin 2 is prevented from flowing out to the electrode region side beyond the relief portions 11, and the sealing resin 2 can be cured in the positions of the relief portions 11.

As a result, the sealing resin 2 can be prevented from contaminating the external electrodes 4 in the electrode region or the like, and, therefore, it is possible to obviate the serious defect that the electrical conduction cannot be secured and the organic EL display apparatus cannot be driven. In other words, it is possible to provide an organic EL display apparatus in which the electrical conduction between the external electrodes and the external terminals is secured and which has high reliability.

Besides, in the case of the multiple-product production mode in which a plurality of display apparatuses are manufactured from a single substrate, it is easier for the sealing resin 2 to diffuse due to the capillarity, but the relief portions 11 formed in the sealing substrate 3 inhibit the outward diffusion of the sealing resin 2 beyond them, thereby promising a higher quality and a higher yield of the organic EL display apparatus. Therefore, the display apparatus and the method of manufacturing the same according to the present invention are very effective in the case of the multiple-product production mode.

While the case of the multiple-product production mode has been described in the above embodiment, the display apparatus and the method of manufacturing the same according to the present invention are applicable also to the case of fabricating a single display apparatus on a single sheet of panel substrate, in the same manner as in the case of the multiple-product production mode.

The present invention is not limited to the details of the above described preferred embodiments. The scope of the invention is defined by the appended claims and all changes and modifications as fall within the equivalence of the scope of the claims are therefore to be embraced by the invention.

What is claimed is:

1. A display apparatus comprising:
a panel substrate provided with light emitting devices and driving electrodes for driving said light emitting devices, said light emitting devices and said driving electrodes forming a light emitting region and an electrode region; and
a sealing substrate adhered to said panel substrate through a sealing resin; wherein
said sealing substrate is provided with a relief portion for said sealing resin at its portion opposed to the outside of said light emitting region in the condition of being adhered to said panel substrate.

2. A display apparatus as set forth in claim 1, wherein said relief portion for said sealing resin is comprised of a groove.

3. A display apparatus as set forth in claim 1, wherein said relief portion for said sealing resin is comprised of a plurality of holes.

4. A display apparatus as set forth in claim 1, wherein said relief portion for said sealing resin is comprised of a rough surface formed in a surface of said sealing substrate.

5. A method of manufacturing a display apparatus comprising a panel substrate provided with light emitting devices and driving electrodes for driving said light emitting devices, said light emitting devices and said driving electrodes forming a light emitting region and an electrode region, and a sealing substrate adhered to said panel substrate through a sealing resin, said method comprising the step of:
providing said sealing substrate with a relief portion for said sealing resin at that portion of said sealing substrate which is opposed to the outside of said light emitting region in the condition where said sealing substrate is adhered to said panel substrate.

6. A method of manufacturing a display apparatus as set forth in claim 5, wherein said relief portion for said sealing resin is comprised of a groove.

7. A method of manufacturing a display apparatus as set forth in claim 5, wherein said relief portion for said sealing resin is comprised of a plurality of holes.

8. A method of manufacturing a display apparatus as set forth in claim 5, wherein said relief portion for said sealing resin is formed by roughening a surface of said sealing substrate.
